(19) United States
(12) Patent Application Publication
(10) Pub. No.: US 2025/0087645 A1
(43) Pub. Date: Mar. 13, 2025

(54) DISPLAY PANEL SUB-ASSEMBLY AND SPLICING DISPLAY APPARATUS

(71) Applicants: BOE MLED Technology Co., Ltd., Beijing (CN); BOE TECHNOLOGY GROUP CO., LTD., Beijing (CN)

(72) Inventor: Zhonghua LI, Beijing (CN)

(21) Appl. No.: 18/580,669

(22) PCT Filed: Aug. 19, 2022
(86) PCT No.: PCT/CN2022/113561

§ 371 Date: Jan. 19, 2024

(51) Int. Cl. H01L 25/075

(52) U.S. Cl. CPC H01L 25/0753

(57) ABSTRACT

The present disclosure provides a display panel sub-assembly, including: at least one display substrate; and a fixing frame, including a bottom plate and at least one substrate fixing structure. The bottom plate is disposed opposite to the at least one display substrate, and has at least one first via in one-to-one correspondence with the at least one substrate fixing structure. Each of the at least one substrate fixing structure passes through the first via to be connected to the bottom plate, and an end of the substrate fixing structure proximate to one of the at least one display substrate is connected to the display substrate through an adhesive, so that the substrate fixing structure is detachably fixed to the display substrate. An embodiment of the present disclosure further provides a splicing display apparatus.

### TECHNICAL FIELD

The present disclosure relates to the field of display, and particularly relates to a display panel sub-assembly and a splicing display apparatus.

### BACKGROUND

A large display screen is typically formed by a plurality of display panel sub-assemblies spliced into a matrix, and display images of the display panel sub-assemblies are combined into a complete image on the large display screen. Each display panel sub-assembly includes a display substrate and a fixing frame. The fixing frame includes a bottom plate on which a foam tape is disposed in a periphery region and part of a central region, and the display substrate is fixed onto the bottom plate by the foam tape.

### SUMMARY

In a first aspect, an embodiment of the present disclosure provides a display panel sub-assembly, including:
at least one display substrate; and
a fixing frame, including a bottom plate and at least one substrate fixing structure, wherein the bottom plate is disposed opposite to the at least one display substrate and has at least one first via in one-to-one correspondence with the at least one substrate fixing structure, each of the at least one substrate fixing structure passes through the corresponding first via to be connected to the bottom plate, and an end of the substrate fixing structure proximate to one of the at least one display substrate is connected to the display substrate through an adhesive, so that the substrate fixing structure is detachably fixed to the display substrate.

In some embodiments, the display substrate includes a bearing substrate, and a plurality of light-emitting elements fixed on a side of the bearing substrate distal from the bottom plate;
the substrate fixing structure includes a first connection member and a second connection member;
the first connection member is located between the bearing substrate and the bottom plate, and an end of the first connection member proximate to the display substrate is connected to the display substrate through an adhesive; and
the second connection member passes through the first via in the bottom plate so that the first connection member and the second connection member are detachably fixed.

In some embodiments, the first connection member and the second connection member clamp and fix the bottom plate.

In some embodiments, the substrate fixing structure further includes an adjustment structure having a structure at least partially located in the first via, an outer side wall of the adjustment structure is movably connected to an inner side wall of the first via, the adjustment structure is configured to be movable along the via in a first direction, and the adjustment structure has a hollow channel extending in the first direction; and
the first connection member is in contact with one end of the adjustment structure proximate to the first connection member, an end of the second connection member distal from the first connection member is in contact with the other end of the adjustment structure distal from the first connection member, the second connection member passes through the hollow channel to be detachably fixed to the second connection member, and the first connection member and the second connection member clamp and fix the adjustment structure.

In some embodiments, the first via is a first threaded hole; and
the adjustment structure includes a hollow screw having external threads matched with internal threads of the first threaded hole, wherein the hollow screw is movable in the first direction by rotating within the first threaded hole.

In some embodiments, the first via includes a first portion and a second portion communicated with each other, the first portion is located on a side of the second portion proximate to the display substrate, the first portion is a blind hole, and the second portion is a through hole;
an orthographic projection of the first connection member in a plane where the bottom plate is located has an area smaller than or equal to an orthographic projection of the first portion in a plane parallel to the plane where the bottom plate is located, and larger than an orthographic projection of the second portion in the plane parallel to the plane where the bottom plate is located; and
the first connection member has a height in the first direction greater than the first portion, and a part of the first connection member is located within the first portion.

In some embodiments, the first connection member includes a connection post, wherein a second threaded hole is formed at an end of the connection post distal from the bearing substrate; and
the second connection member includes a first screw having external threads matched with internal threads of the second threaded hole.

In some embodiments, the second threaded hole is a threaded blind hole.

In some embodiments, an area of an end surface of the connection post proximate to the bearing substrate is 500 mm² to 2000 mm².

In some embodiments, the end surface of the connection post proximate to the bearing substrate has a circular shape.

In some embodiments, the first connection member is made of a material including copper.

In some embodiments, the adhesive includes curing glue or a double-sided tape.

In some embodiments, an end surface of the substrate fixing structure proximate to the display substrate has a circular shape.

In some embodiments, a ratio of a total area of end surfaces of all substrate fixing structures proximate to the display substrate, to an area of the bearing substrate in the display substrate is in a range of 1:5000 to 1:250.

In some embodiments, the total area of end surfaces of all substrate fixing structures proximate to the display substrate is in a range of 500 mm² to 10000 mm².

In some embodiments, an area of an end surface of a single substrate fixing structure proximate to the display substrate is in a range of 50 mm² to 800 mm².

In some embodiments, the at least one substrate fixing structure includes a plurality of substrate fixing structures, the at least one display substrate includes a plurality of display substrates, and each display substrate is connected to one or more of the substrate fixing structures.

In a second aspect, an embodiment of the present disclosure further provides a splicing display apparatus, including a plurality of display panel sub-assemblies, wherein at least one of the display panel sub-assemblies is the display panel sub-assembly according to the first aspect.

In some embodiments, the splicing display apparatus further includes:
a bearing case configured to bear the plurality of the display panel sub-assemblies.

### BRIEF DESCRIPTION OF DRAWINGS

FIG. 1A is an exploded structural view of a display panel sub-assembly in the existing art shown from a non-display side;

FIG. 1B is a schematic structural view showing the fixing frame of FIG. 1A with a foam tape from a display side;

FIG. 2 is a schematic structural view of a display panel sub-assembly according to an embodiment of the present disclosure;

FIG. 3A is a schematic view of a side of the fixing frame of FIG. 2 facing a display substrate;

FIG. 3B is a schematic view of a side of the fixing frame of FIG. 2 facing away from a display substrate;

FIG. 3C is a schematic sectional view taken along line A-A′ of FIG. 3A;

FIG. 4 is a schematic sectional view of a location with a substrate fixing structure according to an embodiment of the present disclosure;

FIG. 5 is another schematic sectional view of a location with a substrate fixing structure according to an embodiment of the present disclosure;

FIG. 6 is a schematic view illustrating a substrate fixing structure used to control a display substrate to move in a first direction according to an embodiment of the present disclosure; and

FIG. 7 is a schematic structural view of a splicing display apparatus according to an embodiment of the present disclosure.

### DETAIL DESCRIPTION OF EMBODIMENTS

To improve understanding of the technical solution of the present disclosure for those skilled in the art, the present disclosure will be described in detail below with reference to accompanying drawings and specific implementations.

The present disclosure will be described in detail below with reference to the accompanying drawings. Throughout the drawings, elements the same as or similar to each other are indicated by similar reference signs. For the sake of clarity, various parts in the figures are not all drawn to scale. Moreover, some well-known parts may not be shown in the figures.

For better understanding of the present disclosure, many specific details, such as structures, materials, dimensions, processing, and techniques of components, of the present disclosure are described below. However, the present disclosure may be implemented without these specific details, as will be understood by those skilled in the art.

The words “first”, “second” and similar terms used in the embodiments of the present disclosure do not denote any order, quantity, or importance, but are used merely for distinguishing different components from each other. Likewise, the word “comprising” or “including” or the like means that the element or item preceding the word contains elements or items that appear after the word or equivalents thereof, but does not exclude other elements or items. The reference to two structures “connected” or “coupled” together or the like refer to not only the two structures connected by directly contacting each other, but also the two structures indirectly connected through other structures.

In addition, as used herein, the reference to two structures “fixed” together merely indicates that the two structures are not separable under a certain condition or at a certain moment, but may be separable under other conditions or at other moments. For example, a screw is fixed to a corresponding screw hole when the screw is screwed into the screw hole, but the screw may be unscrewed from the screw hole so that the screw is separated from the screw hole.

In addition, as used herein, a range defined as A to B includes both end values A and B.

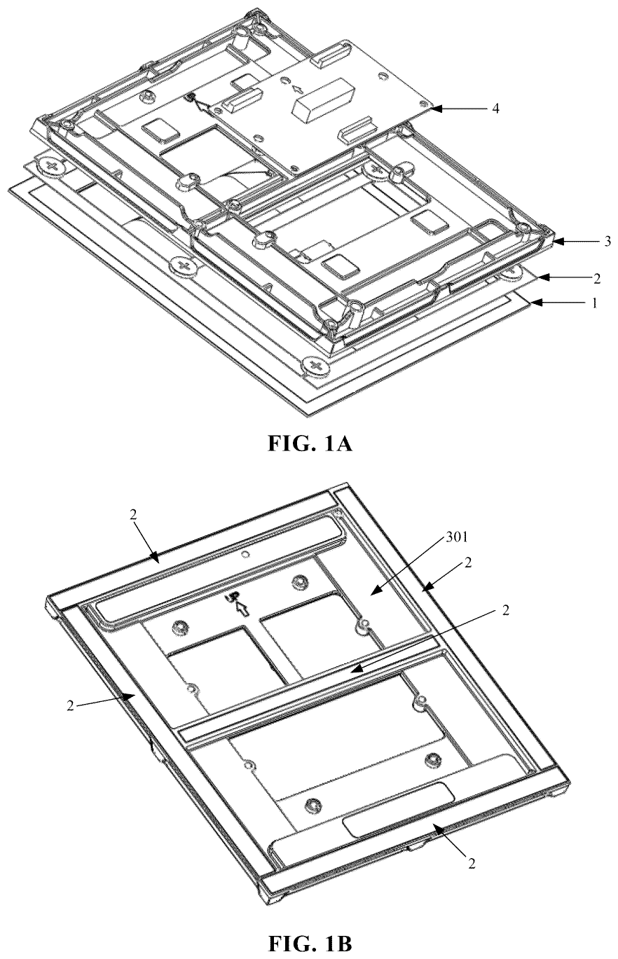

FIG. 1A is an exploded structural view of a display panel sub-assembly in the existing art shown from a non-display side, and FIG. 1B is a schematic structural view showing the fixing frame of FIG. 1A with a foam tape from a display side. As shown in FIGS. 1A and 1B, a display panel sub-assembly includes a display substrate 1, a fixing frame 3, and a signal adapter board 4. The fixing frame 3 includes a bottom plate 301 having a bearing surface 301a and a mounting surface 301b, where the bearing surface 301a is configured to fix the display substrate 1. The signal adapter board 4 is electrically connected to the display substrate 1 through an FPC, an electrical signal may be written into the display substrate 1 through the signal adapter board 4, and the signal adapter board 4 is generally fixed to the mounting surface 301b of the bottom plate 301.

In the existing art, a periphery of the display substrate 1 is fixed to a periphery of the mounting surface 301 of the bottom plate 301 by a foam tape 2. Meanwhile, part of a central region of the display substrate 1 is also fixed to a central region of the bottom plate 301 by the foam tape 2. In other words, one side of the foam tape 2 is fixedly bonded to the display substrate 1, and the other side of the foam tape 2 is fixedly bonded to the bottom plate 301.

It is found in practical applications that since the foam tape 2 has extremely strong viscosity and arranged over a relatively large area, a ratio of an arrangement area of the foam tape to an area of the bearing substrate in the display substrate 1 is typically about 1:50. For example, if the bearing substrate in the display substrate 1 has a size of 1500 mm*1680 mm, a foam tape with a width of about 8 mm may be arranged in a periphery of the bearing substrate (the arrangement area of the foam tape is about 50000 mm²). If the bearing substrate in the display substrate 1 is made of glass, which is fragile, it is difficult to intactly separate the display substrate 1 and the fixing frame 3 after the two are fixed by the foam tape 2, leading to the problems of inconvenient repair and poor yield of the display panel during assembly.

To effectively solve at least one of the technical problems in the existing art, an embodiment of the present disclosure provides a display panel sub-assembly.

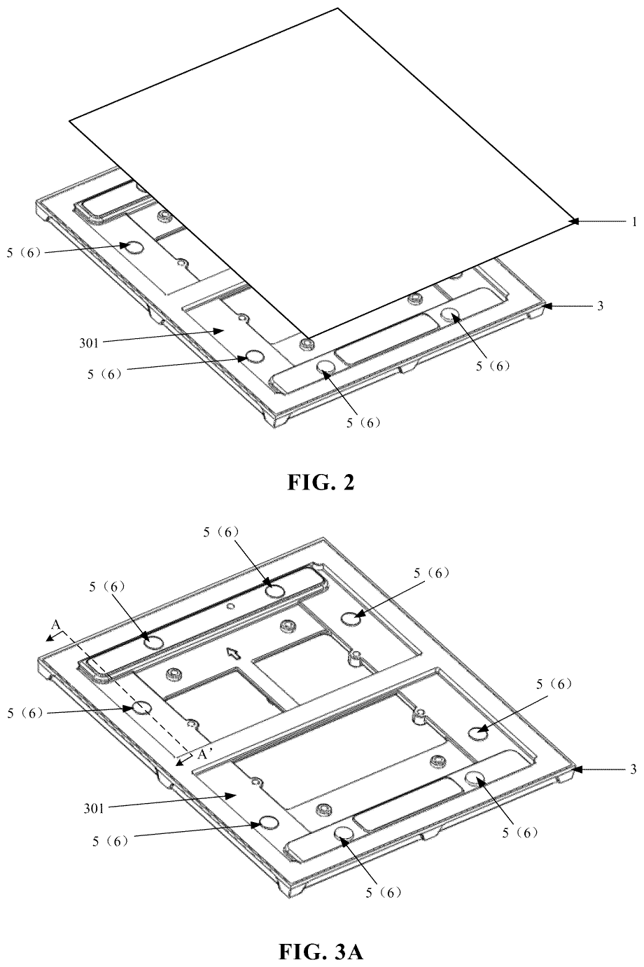

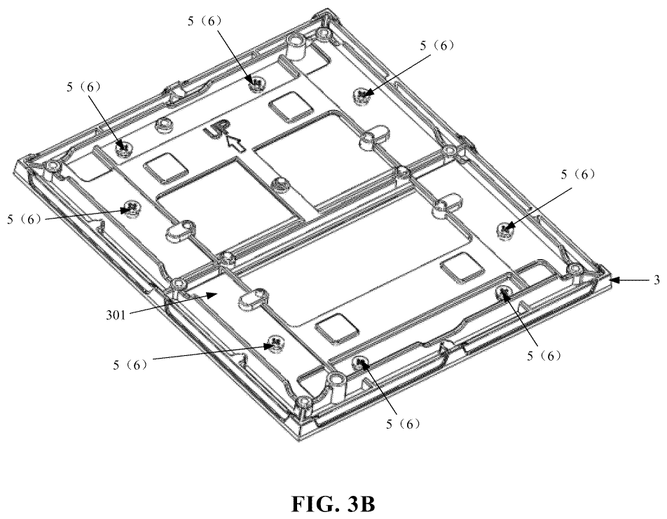

FIG. 2 is a schematic structural view of a display panel sub-assembly according to an embodiment of the present disclosure, FIG. 3A is a schematic view of a side of the fixing frame of FIG. 2 facing a display substrate, FIG. 3B is a schematic view of a side of the fixing frame of FIG. 2 facing away from a display substrate, and FIG. 3C is a schematic sectional view taken along line A-A′ of FIG. 3A. As shown in FIGS. 2 to 3C, the display panel sub-assembly includes: at least one display substrate 1 and a fixing frame 3.

The fixing frame 3 (for example, an aluminum frame) includes: a bottom plate 301 and at least one substrate fixing structure 5. The bottom plate 301 is disposed opposite to the display substrate 1, and has at least one first via 7 in one-to-one correspondence with the substrate fixing structure 5. The substrate fixing structure 5 passes through the first via 7 to be connected to the bottom plate 301, and an end of the substrate fixing structure 5, which is proximate to the display substrate 1, is connected to the display substrate 1 through an adhesive 6, so that the substrate fixing structure 5 is detachably fixed to the display substrate 1.

Different from the technical solution in the existing art where the display substrate 1 is fixed to the bottom plate 301 by the foam tape 2, in the embodiment of the present disclosure, at least one substrate fixing structure 5 fixed to the bottom plate 301 is provided on the bottom plate 301, and connected to the display substrate 1 through the adhesive 6, so that the substrate fixing structure 5 is detachably fixed to the display substrate 1 and thereby, the display substrate 1 is fixed to the fixing frame 3. After the display substrate 1 is fixed to the fixing frame 3, the display substrate 1 remains separated from the bottom plate 301.

In an embodiment of the present disclosure, the display substrate 1 is merely fixed to the substrate fixing structure 5 by the adhesive 6, while a relatively small attachment area may be designed between a single substrate fixing structure 5 and the display substrate 1, and a plurality of substrate fixing structures 5 may be distributed dispersedly, so that each substrate fixing structure 5 can be separated from the display substrate 1 in a relatively easy manner. Therefore, the technical solution of the present disclosure can effectively improve the technical problem of easy damage to the glass when the glass-based display substrate 1 is disassembled in the existing art.

In addition, in an embodiment of the present disclosure, a plurality of substrate fixing structures 5 may be provided, and by reasonably designing positions of the plurality of substrate fixing structures 5 (for example, providing the plurality of substrate fixing structures 5 uniformly arranged and spaced at intervals in a region where the foam tape is provided, as in the existing art), the plurality of substrate fixing structures 5 may cooperate to provide stable fixing of the display substrate 1. In other words, in the embodiment of the present disclosure, a single substrate fixing structure 5 can be easily separated from the display substrate 1, while a plurality of substrate fixing structures 5 can work together to stably fix the display substrate 1.

In some embodiments, a ratio of a total area of end surfaces of all substrate fixing structures 5 proximate to the display substrate, to an area of the bearing substrate in the display substrate 1 is in a range of 1:5000 to 1:250, which is much less than the ratio (about 1:50) of the arrangement area of the foam tape to the area of the bearing substrate in the display substrate in the conventional technology. It can be seen that given the bearing substrate in the display substrate, the total area of the adhesive desired in the present disclosure will be far smaller than that of the foam tape in the existing art.

In some embodiments, the total area of end surfaces of all substrate fixing structures 5 proximate to the display substrate is 500 mm² to 10000 mm². With such a design, it is ensured that the plurality of substrate fixing structures 5 cooperate to provide stable fixing of the display substrate 1.

In some embodiments, an area of an end surface of a single substrate fixing structure 5 proximate to the display substrate is in a range of 50 mm² to 800 mm². With such a design, it is ensured that a single substrate fixing structure 5 can be easily separated from the display substrate 1.

In an embodiment of the present disclosure, the display panel sub-assembly is assembled through a process including: firstly providing a fixing frame 3 with a plurality of first vias 7; then providing a corresponding substrate fixing structure 5 in each first via 7, so that the substrate fixing structure 5 is fixed to the bottom plate 301; then providing an adhesive piece 6 on a side of each substrate fixing structure 5 distal from the bottom plate 301; and finally fixing the glass-based display substrate 1 and each substrate fixing structure 5 with a jig through the adhesive 6.

In some embodiments, the adhesive 6 includes a double-sided tape or glue (e.g., photo-curing glue or thermal curing glue).

To disassemble the display panel sub-assembly (e.g., to repair the display substrate 1), the disassembly process includes: firstly, separating each substrate fixing structure 5 from the bottom plate 301, so that the display substrate 1 is separated from the fixing frame 3; and then removing each substrate fixing structure 5 fixed on the display substrate 1. Due to the relatively small attachment area between a single substrate fixing structure 5 and the display substrate 1, an adhesive force between the two is not very large, and thus, the two can be separated by a small force.

As an alternative, when the adhesive 6 is a double-sided tape, a region where the double-sided tape is located may be firstly heated appropriately to weaken an adhesive force of the double-sided tape, and then the substrate fixing structure 5 is separated from the display substrate 1.

As another alternative, when the adhesive 6 is an organic adhesive (e.g., photo-curing glue or thermal curing glue), the adhesive 6 may be partially or completely removed by an organic solvent (e.g., a stripping liquid), and then the substrate fixing structure 5 is separated from the display substrate 1.

It should be noted that after being separated from the display substrate 1, the substrate fixing structure 5 can be reused, so that no waste of materials is caused.

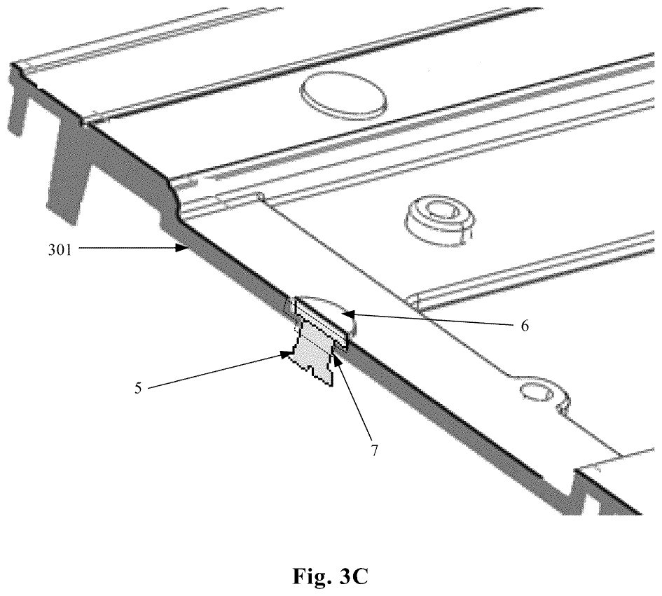

FIG. 4 is a schematic sectional view of a location with a substrate fixing structure according to an embodiment of the present disclosure. As shown in FIG. 4, in some embodiments, the display substrate 1 includes: a bearing substrate 101, and a plurality of light-emitting elements 102 fixed on a side of the bearing substrate 101 distal from the bottom plate 301.

The bearing substrate 101 includes a substrate provided with a circuit and a pad for mounting and soldering an electronic component (such as a light-emitting element, a mini LED or a micro LED). The substrate may be made of glass (i.e., the display substrate 1 is glass-based); and apparently, the substrate may also be made of plastic, quartz, metal, or the like.

In addition, the bearing substrate 101 may be an FR4 (A material standard specified by the NEMA (National Electrical Manufacturers Association)) type printed circuit board composed of an insulation board, a connection wiring layer, and a pad for assembling and soldering an electronic component (e.g., a light-emitting element, a driver element, a sensor element, etc.), where the insulation board and the connection wiring layer may each have multiple layers, and connection wires in different layers may be connected through vias provided in the insulation board.

The light-emitting element 102 may be a micro LED or a mini LED which can be mounted on a first side (generally referred to as a front side) of the bearing substrate 101 through a die bonding process. On a second side (generally referred to as a back side) of the bearing substrate 101, there is provided a circuit board (not shown) configured to supply an electrical signal to the light-emitting element on the first side.

The substrate fixing structure 5 includes: a first connection member 501 and a second connection member 502. The first connection member 501 is located between the bearing substrate 101 and the bottom plate 301, and an end of the first connection member 501, which is proximate to the display substrate 1, is connected to the display substrate 1 through an adhesive. The second connection member 502 passes through the first via 7 in the bottom plate 301 so that the first connection member 501 and the second connection member 502 are detachably fixed.

In some embodiments, the first connection member 501 and the second connection member 502 clamp and fix the bottom plate 301 to fix the substrate fixing structure 5 to the bottom plate 301.

In the assembly process of the display panel sub-assembly, the first connection member 501 may be firstly disposed on one side of the bottom plate 301 facing the display substrate 1, and then the second connection member 502 passes through the corresponding first via 7 from the other side of the bottom plate 301 facing away from the display substrate 1 to be fixed to the first connection member 501, so that the first connection member 501 and the second connection member 502 clamp and fix the bottom plate 301.

In the disassembly process of the display panel sub-assembly, the first connection member 501 and the second connection member 502 may be unfixed, then the display substrate 1 fixed to the first connection member 501 through the adhesive 6 is separated from the fixing frame 3, and then the first connection member 501 is separated from the display substrate 1.

In some embodiments, the first connection member 501 includes a connection post, and a second threaded hole 5011 is formed at an end of the connection post distal from the bearing substrate 101. The second connection member 502 includes a first screw having external threads matched with internal threads of the second threaded hole 5011.

In some embodiments, the second threaded hole 5011 is a threaded blind hole. In other words, the second threaded hole 5011 does not completely pass through the connection post, and in this case, an end of the connection post distal from the bottom plate 301 has a relatively intact end surface, which is convenient for subsequent provision of the adhesive 6, and at the same time, effectively prevents the first screw from extending out of the end of the connection post distal from the bottom plate 301 and affecting the subsequent assembly.

Apparently, the second threaded hole in the present disclosure may also be a threaded through hole, which also falls in the protection scope of the present disclosure.

In addition, the case where the first connection member 501 is fixed to the second connection member 502 through threaded connection as described in the embodiment of the present disclosure is merely an optional implementation of the present disclosure, and does not form any limitation to the technical solution of the present disclosure. In the embodiments of the present disclosure, the first connection member 501 and the second connection member 502 may also be fixed in other detachable fixing methods, such as snap-fit fixing; which are not listed here one by one.

It is found in practical applications that when a plurality of display panel sub-assemblies are fixed onto a bearing case to obtain a splicing display apparatus, there may be a large segment difference (for example, a segment difference greater than 2 mm) in a first direction Z between display substrates 1 of two or more display panel sub-assemblies, which may affect the final display effect of the splicing display apparatus. To effectively improve, and even completely eliminate, the above technical problem, an embodiment of the present disclosure provides a novel technical solution.

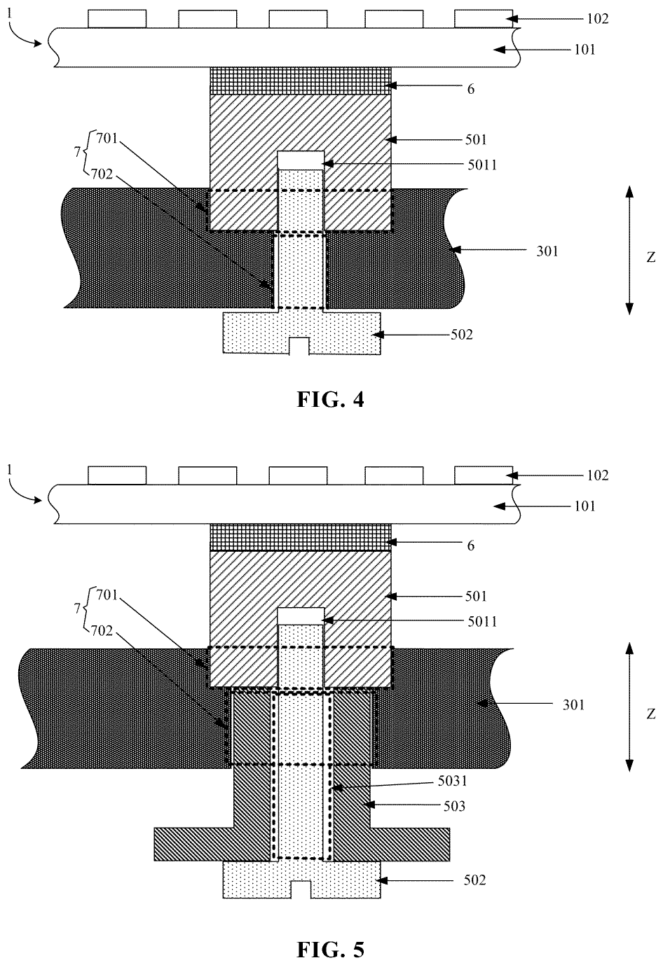

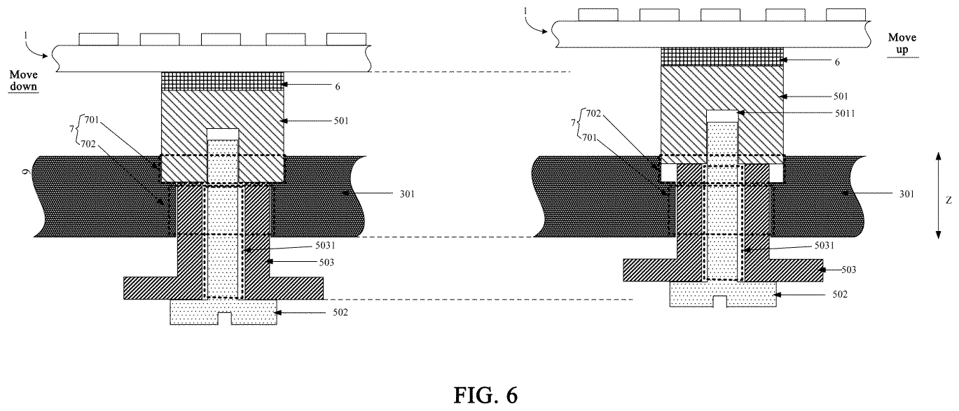

FIG. 5 is another schematic sectional view of a location with a substrate fixing structure according to an embodiment of the present disclosure, and FIG. 6 is a schematic view illustrating a substrate fixing structure 5 used to control a display substrate 1 to move in a first direction Z according to an embodiment of the present disclosure. As shown in FIGS. 5 and 6, unlike the solution provided in the above embodiments in which the first connection member 501 and the second connection member 502 clamp and fix the bottom plate 301, in the solution shown in FIG. 5, the substrate fixing structure 5 includes not only the first connection member 501 and the second connection member 502, but also an adjustment structure 503. The adjustment structure 503 has a structure at least partially located in the first via 7, an outer side wall of the adjustment structure 503 is movably connected to an inner side wall of the first via 7, the adjustment structure 503 is configured to be movable along the via in a first direction Z, and the adjustment structure 503 has a hollow channel 5031 extending in the first direction Z. The first connection member 501 is in contact with one end of the adjustment structure 503 proximate to the first connection member 501, an end of the second connection member 502 distal from the first connection member 501 is in contact with the other end of the adjustment structure 503 distal from the first connection member 501, the second connection member 502 passes through the hollow channel 5031 to be detachably fixed to the second connection member 502, and the first connection member 501 and the second connection member 502 clamp and fix the adjustment structure 503.

In an embodiment of the present disclosure, the second connection member 502 passes through the hollow channel 5031 in the adjustment structure 503 to be connected to the corresponding first connection member 501, and meanwhile, an end of the first connection member 501 proximate to the adjustment structure 503 and an end of the second connection member 502 distal from the first connection member 501 are respectively connected to two ends of the adjustment structure 503, that is, the second connection member 502 and the first connection member 501 clamp and fix the adjustment structure 503 in the first direction Z while being fixed to each other. While the adjustment structure 503 is moved along the first via 7 in the first direction Z, the first connection member 501 and the display substrate 1 fixed to the first connection member 501 are synchronously driven to move in the first direction Z relative to the bottom plate 301, so as to adjust a position of the display substrate 1 relative to the bottom plate 301 in the first direction Z.

As can be seen, the technical solution shown in FIG. 5 can enable the display substrates 1 to move in the first direction Z, so that in the case of a large segment difference in the first direction Z between display substrates 1 of two or more display panel sub-assemblies in the splicing display apparatus, positions of the display substrates 1 in at least some of the display panel sub-assemblies can be adjusted in the first direction Z, to reduce the segment difference between any two display substrates 1 in the splicing display apparatus (for example, the segment difference can be reduced to −0.05 mm to +0.05 mm), thereby improving the display effect of the splicing display apparatus.

In addition, in an embodiment of the present disclosure, when a plurality of substrate fixing structures 5 are provided, adjustment structures 503 in some of the substrate fixing structures 5 in the display panel sub-assembly can be adjusted according to actual needs, so as to adjust a distance between a partial region of the display substrate 1 and the bottom plate 301; that is, a position of a part of the display substrate 1 can be adjusted in the first direction Z.

In some embodiments, the first via 7 is a first threaded hole; and the adjustment structure 503 includes: a hollow screw having external threads matched with internal threads of the first threaded hole, where the hollow screw is movable in the first direction Z by rotating within the first threaded hole. In other words, the hollow screw can be moved in the first direction Z by rotating, so as to drive the display substrate 1 to move synchronously in the first direction Z.

With continued reference to FIG. 5, in some embodiments, the first connection member 501 includes a connection post, and a second threaded hole is formed at an end of the connection post distal from the bearing substrate 101. The second connection member 502 includes: a first screw having external threads matched with internal threads of the second threaded hole. In some embodiments, the second threaded hole is a threaded blind hole. For description about the detachable fixation between the first connection member 501 and the second connection member 502, reference may be made to the contents in the foregoing embodiments, and details are not repeated here.

Referring to FIGS. 4 and 5, in some embodiments, the first via 7 includes a first portion 701 and a second portion 702 communicated with each other, the first portion 701 is located on a side of the second portion 702 proximate to the display substrate 1, the first portion 701 is a blind hole, and the second portion 702 is a through hole. An orthographic projection of the first connection member 501 in a plane where the bottom plate 301 is located has an area smaller than or equal to an orthographic projection of the first portion 701 in a plane parallel to the plane where the bottom plate 301 is located, and larger than an orthographic projection of the second portion 702 in the plane parallel to the plane where the bottom plate 301 is located. The first connection member 501 has a height in the first direction Z greater than the first portion 701, and a part of the first connection member 501 is located within the first portion 701.

In an embodiment of the present disclosure, by forming the first portion 701 (i.e., the blind hole) for receiving the first connection member 501 in the bottom plate 301, it is possible to ensure that the first connection member 501 has a sufficiently large size in the first direction Z to facilitate preparation and assembly of the first connection member 501, while the display substrate 1 and the bottom plate 301 have a relatively small gap in the first direction Z (ensuring that the display panel sub-assembly is relatively thin).

Apparently, in an embodiment of the present disclosure, the first via 7 may include only the second portion 702 but not the first portion 701, and in this case, the first connection member 501 is placed on a side surface of the bottom plate 301 facing the display substrate 1, which also falls in the protection scope of the present disclosure.

Referring to FIGS. 4 and 5, in some embodiments, an area of an end surface of the connection post proximate to the bearing substrate 101 is in a range of 50 mm² to 800 mm². With such arrangement, the connection post can be conveniently separately from the display substrate 1 while ensuring the stable fixation between the connection post and the display substrate 1 through the adhesive 6.

In some embodiments, the end surface of the connection post proximate to the bearing substrate 101 has a circular shape. Apparently, the end surface of the connection post proximate to the bearing substrate 101 may also have a regular shape such as a triangular shape, a quadrangular shape, a polygonal shape or the like, or may have an irregular shape.

In some embodiments, the first connection member 501 is made of a material including copper. Due to good affinity with glue or tapes, a copper surface can be well attached with glue or tapes, thereby achieving a relatively optimal bonding and fixing effect with a relatively small attachment area.

In some embodiments, 4 to 20, such as 4, 6, 8, 10, 16, or 20, substrate fixing structures 5 are provided. The number of substrate fixing structures 5 and the arrangement position of each substrate fixing structure 5 may be designed and adjusted in advance according to actual needs, which is not limited herein.

In the embodiments of the present disclosure, since the fixing manner between the display substrate 1 and the fixing frame 3 is changed, the fixing frame 3 and the display substrate 1 are not limited to the one-to-one correspondence relationship in the existing art. In an embodiment of the present disclosure, a plurality of display substrates 1 may be fixed to one fixing frame 3, a plurality of substrate fixing structures 5 are provided, each substrate fixing structure 5 is connected to one of the display substrates 1, and each display substrate 1 is connected to one or more of the substrate fixing structures 5. The number of display substrates 1 fixed to the fixing frame 3 is not limited in the technical solution of the present disclosure.

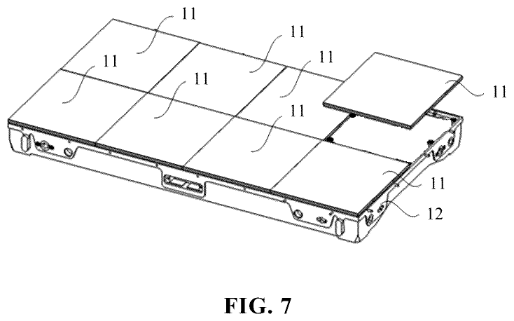

Based on the same concept, an embodiment of the present disclosure further provides a splicing display apparatus. FIG. 7 is a schematic structural view of a splicing display apparatus according to an embodiment of the present disclosure. As shown in FIG. 7, the splicing display apparatus includes a plurality of display panel sub-assemblies 11, where at least one of the display panel sub-assemblies 11 is the display panel sub-assembly according to any of the above embodiments. For detailed description of the display panel sub-assembly 11, reference may be made to the contents in the foregoing embodiments, and details are not repeated here.

In some embodiments, the splicing display apparatus further includes a bearing case 12; and the bearing case 12 is configured to bear the plurality of the display panel sub-assemblies 11.

The embodiments of the present disclosure are as described above, where not all details of the embodiments are elaborated, and the present disclosure is not intended to be limited to these specific embodiments. Apparently, many modifications and variations are possible in light of the above description. The description has chosen and described these specific embodiments in detail for better illustration of the principles and practical applications of the present disclosure so that those skilled in the art can make good use of the present disclosure as well as modified applications based on the present disclosure. The present disclosure is intended to be limited only by the claims and the full scope and equivalents thereof.

1. A display panel sub-assembly, comprising:
at least one display substrate; and
a fixing frame, comprising a bottom plate and at least one substrate fixing structure, wherein the bottom plate is disposed opposite to the at least one display substrate and has at least one first via in one-to-one correspondence with the at least one substrate fixing structure, each of the at least one substrate fixing structure passes through the corresponding first via to be connected to the bottom plate, and an end of the substrate fixing structure proximate to one of the at least one display substrate is connected to the display substrate through an adhesive, so that the substrate fixing structure is detachably fixed to the display substrate.

2. The display panel sub-assembly according to claim 1, wherein the display substrate comprises a bearing substrate, and a plurality of light-emitting elements fixed on a side of the bearing substrate distal from the bottom plate;
the substrate fixing structure comprises a first connection member and a second connection member;
the first connection member is located between the bearing substrate and the bottom plate, and an end of the first connection member proximate to the display substrate is connected to the display substrate through an adhesive; and
the second connection member passes through the first via in the bottom plate to be detachably fixed to the first connection member.

3. The display panel sub-assembly according to claim 2, wherein the first connection member and the second connection member clamp and fix the bottom plate.

4. The display panel sub-assembly according to claim 2, wherein the substrate fixing structure further comprises an adjustment structure having a structure at least partially located in the first via, an outer side wall of the adjustment structure is movably connected to an inner side wall of the first via, the adjustment structure is configured to be movable along the via in a first direction, and the adjustment structure has a hollow channel extending in the first direction; and
the first connection member is in contact with one end of the adjustment structure proximate to the first connection member, an end of the second connection member distal from the first connection member is in contact with the other end of the adjustment structure distal from the first connection member, the second connection member passes through the hollow channel to be detachably fixed to the first connection member, and the first connection member and the second connection member clamp and fix the adjustment structure.

5. The display panel sub-assembly according to claim 4, wherein the first via is a first threaded hole; and
the adjustment structure comprises a hollow screw having external threads matched with internal threads of the first threaded hole, wherein the hollow screw is movable in the first direction by rotating within the first threaded hole.

6. The display panel sub-assembly according to claim 4, wherein the first via comprises a first portion and a second portion communicated with each other, the first portion is located on a side of the second portion proximate to the display substrate, the first portion is a blind hole, and the second portion is a through hole;
an orthographic projection of the first connection member in a plane where the bottom plate is located has an area smaller than or equal to an orthographic projection of the first portion in a plane parallel to the plane where the bottom plate is located, and larger than an orthographic projection of the second portion in the plane parallel to the plane where the bottom plate is located; and
the first connection member has a height in the first direction greater than the first portion, and a part of the first connection member is located within the first portion.

7. The display panel sub-assembly according to claim 2, wherein the first connection member comprises a connection post, wherein a second threaded hole is formed at an end of the connection post distal from the bearing substrate; and
the second connection member comprises a first screw having external threads matched with internal threads of the second threaded hole.

8. The display panel sub-assembly according to claim 7, wherein the second threaded hole is a threaded blind hole.

9. The display panel sub-assembly according to claim 2, wherein the first connection member is made of a material comprising copper.

10. The display panel sub-assembly according to claim 9, wherein the adhesive comprises curing glue or a double-sided tape.

11. The display panel sub-assembly according to claim 1, wherein an end surface of the substrate fixing structure proximate to the display substrate has a circular shape.

12. The display panel sub-assembly according to claim 1, wherein a ratio of a total area of end surfaces of all substrate fixing structures proximate to the display substrate, to an area of the bearing substrate in the display substrate is in a range of 1:5000 to 1:250.

13. The display panel sub-assembly according to claim 1, wherein a total area of end surfaces of all substrate fixing structures proximate to the display substrate is in a range of 500 mm² to 10000 mm².

14. The display panel sub-assembly according to claim 1, wherein an area of an end surface of a single substrate fixing structure proximate to the display substrate is in a range of 50 mm² to 800 mm².

15. The display panel sub-assembly according to claim 1, wherein the at least one substrate fixing structure comprises 4 to 20 substrate fixing structures.

16. The display panel sub-assembly according to claim 1, wherein the at least one substrate fixing structure comprises a plurality of substrate fixing structures, the at least one display substrate comprises a plurality of display substrates, and each display substrate is connected to one or more of the substrate fixing structures.

17. A splicing display apparatus, comprising a plurality of display panel sub-assemblies, wherein at least one of the display panel sub-assemblies is the display panel sub-assembly according to claim 1.

18. The splicing display apparatus according to claim 17, further comprising:
a bearing case configured to bear the plurality of the display panel sub-assemblies.

19. The display panel sub-assembly according to claim 2, wherein the first via comprises a first portion and a second portion communicated with each other, the first portion is located on a side of the second portion proximate to the display substrate, the first portion is a blind hole, and the second portion is a through hole;
an orthographic projection of the first connection member in a plane where the bottom plate is located has an area smaller than or equal to an orthographic projection of the first portion in a plane parallel to the plane where the bottom plate is located, and larger than an orthographic projection of the second portion in the plane parallel to the plane where the bottom plate is located; and
a part of the first connection member is located within the first portion.

20. The display panel sub-assembly according to claim 3, wherein the first via comprises a first portion and a second portion communicated with each other, the first portion is located on a side of the second portion proximate to the display substrate, the first portion is a blind hole, and the second portion is a through hole;
an orthographic projection of the first connection member in a plane where the bottom plate is located has an area smaller than or equal to an orthographic projection of the first portion in a plane parallel to the plane where the bottom plate is located, and larger than an orthographic projection of the second portion in the plane parallel to the plane where the bottom plate is located; and
a part of the first connection member is located within the first portion.
